(19) United States
(12) Patent Application Publication
(10) Pub. No.: US 2019/0100836 A1
(43) Pub. Date: Apr. 4, 2019

(54) COATED PISTON RING HAVING A PROTECTIVE LAYER

(71) Applicant: FEDERAL-MOGUL BURSCHEID GMBH, BURSCHEID (DE)

(72) Inventor: PETER-KLAUS ESSER, KURTEN (DE)

(21) Appl. No.: 16/095,048

(22) PCT Filed: Mar. 1, 2017
(86) PCT No.: PCT/EP2017/054747

§ 371 Date: Oct. 19, 2018

(30) Foreign Application Priority Data
Apr. 20, 2016 (DE) 10 2016 107 296.6
May 2, 2016 (DE) 10 2016 108 088.8

(51) Int. Cl. C23C 14/06; C23C 14/58; C23C 14/04; C23C 28/04; C23C 28/00; C23C 14/34; C23C 14/32; F16J 9/26

(52) U.S. Cl. CPC C23C 14/0611; C23C 14/0641; C23C 14/5886; C23C 14/046; C23C 28/044; F16J 9/26; C23C 28/322; C23C 28/343; C23C 28/347; C23C 14/34; C23C 14/325; C23C 28/046

(57) ABSTRACT

A piston ring is provided with is furnished with a diamond-like carbon (DLC) layer as a functional/wear protection layer, wherein the DLC layer is covered with a protective layer, the material of which differs from that of the DLC layer, and the material of which has higher thermal resistance that the material of the DLC layer. In addition, a method is provided for producing a piston ring with a DLC wear protection layer, in whose surface the protective layer is present in the form of deposits in depressions created by the surface roughness.

### FIELD OF THE INVENTION

The present invention relates to a coating of a piston ring, particularly a gasket, or use on a piston of an internal combustion engine.

### RELATED ART

Sliding elements such as piston rings in internal combustion engines must operate for the longest possible service life both with as little friction and as little wear as possible. In order to reduce the friction, which is associated directly with the fuel consumption of the internal combustion engine, and prolong service live, it is generally known to furnish sliding elements of such kind with a friction reducing coating that protects against wear. For this, a DLC coating (Diamond Like Carbon) for example, or a nitriding layer is used, which is generally known to the person skilled in the art. Various processes are used for applying a DLC layer. A PA-CVD (Plasma-Assisted Chemical Vapour Deposition) process is often used because of its high coating rates and relatively low costs. The use of PVD (Physical Vapour Deposition) processes is also known.

In this context, the requirements in terms of wear and fitting precision are particularly high on the piston ring, the gasket closest to the combustion chamber, in order to satisfy the requirements for low blowby and minimal oil consumption, since the gasket is exposed to the greatest gas pressure and the highest thermal load. There is therefore a need to improve the properties of piston rings furnished with function/wear protection coatings.

An optimal running-in behaviour is also necessary in order to prolong the service life of the ring. The ring contour of the piston ring muse also be optimised and it must be possible to assess it through the additional interaction of the internal stresses between the base material and the coating, which have different strengths, in order to prevent the coating from being damaged prematurely.

### SUMMARY OF THE INVENTION

According to the invention, the problem is solved with a piston ring comprising a piston ring body to which a DLC coat is applied as a functional coating on the outer surface, at least on the bearing surface thereof, wherein a protective layer is applied over the functional coating at least one partial surfaces of the piston ring bearing surface, and wherein the protective layer consists of a material that differs from the material of the functional coating and is resistant to higher temperatures than the functional coating.

According to one aspect, the protective layer may be applied via a PVD process.

According to a further aspect of the present invention, the thickness of the protective layer is less than 5 μm, preferably less than 2 μm, most preferably less than 1 μm.

According to another aspect, the protective layer may consist of a metal or a metal nitride.

According to one aspect, a protective layer is applied to the entire piston ring bearing surface.

According to a further aspect of the present invention, a protective layer may possibly not be applied to the piston ring bearing surface in a region surrounding the pivot point, and a protective layer may be applied to the rest of the piston ring bearing surface, possibly including the running edges outside of this region.

According to one aspect, the functional coating/wear protection layer may be formed as a DLC layer that contains no hydrogen or halogens.

According to one aspect, the protective layer may be present in the form of surface deposits in depressions in the functional coating.

According to one aspect, when the functional coating has a layer thickness of less than 10 μm the surface deposits of the protective layer constitute an area percentage between 10% and 30% of the total surface area, when the functional coating has a layer thickness of more than 10 μm the surface deposits constitute an area percentage between 20% and 40% of the total surface area.

According to one aspect, the Rpk roughness value on the piston ring bearing surface may be in the range from 0.03 μm to 0.1 μm, and the Rk roughness value may be in the range from 0.25 μm to 0.3 μm.

The problem is further solved according to the invention with a method for producing a piston ring, comprising the provision of a piston ring body; the application of a DLC layer as a functional coating at least to the bearing surface of the piston ring body; the application of a protective layer to the functional coating; and partial removal of the protective layer so that deposits are only left in depressions in the surface of the functional coating.

According to one aspect of the method, the piston ring body, particularly those outer surfaces which are furnished with a functional coating may be roughened before the functional coating is applied.

According to one aspect of the method, the functional coating may be applied by an electric arc process or a sputtering process.

According to one aspect of the method, the functional coating may have a Rpk roughness value in the range from 0.15 μm to 0.5 μm and a Rk roughness value in the range from 0.3 μm to 0.7 μm after it is applied.

According to one aspect of the method, the protective layer may be applied in a PVD process.

According to one aspect of the method, the material of the protective layer may comprise a metal, a metal alloy or a metal nitride, preferably chromium, aluminium, titanium nitride or vanadium nitride.

According to one aspect of the method, the application thickness of the material of the protective layer may be between 0.05 μm and 1 μm, preferably between 0.2 μm and 0.4 μm when the layer thickness of the functional coating is greater than 20 μm, and preferably between 0.05 μm and 0.4 μm, more preferably between 0.1 μm and 0.2 μm when the layer thickness of the functional coating is less than 20 μm.

According to one aspect of the method, the removal step may comprise lapping, particularly cylindrical lapping.

According to a further aspect of the method, the removal step may be continued until the area percentage of the surface deposits is between 10% and 30% of the total surface area when the functional coating has a layer thickness of less than 10 μm, and between 20% and 40% of the total surface area when the functional coating has a layer thickness of wore than 10 μm.

### DETAILED DESCRIPTION OF THE INVENTION

In the following text, the present invention will be described with reference to various embodiments and variant features.

The invention relates to a protective layer for a piston ring furnished with a functional/wear protection layer, wherein the functional coating consists of diamond-like carbon (DLC). DLC coatings comprise tetrahedral amorphous carbon layers, also called “ta-C”, which have sp3 hybridised bonds, which are responsible for the formation of a diamond-like structure. A hard amorphous carbon-based layer of such kind is able to reduce friction and exhibit a thermal resistance in the range from about 450 to 550° C. and a coating thickness from 2 μm up to 40 μm. The DLC layer is preferably a DLC layer that contains no hydrogen or halogens.

The DLC layer/functional coating covers at least a partial region of the piston ring bearing surface, but optionally may also cover other outer surface regions of the piston ring, the piston ring flanks, for example.

The DLC layer is further coated with a protective layer consisting of a material that differs from the material of the DLC layer, and which has greater heat resistance than the material of the DLC layer, for example in the range from 550 to 650° C. In this context, the coverage is applied to at least a part of the piston ring bearing surface, but is may also extend over the entire bearing surface.

The bearing surface of the piston ring generally has a domed or conical profile, that is to say in a cross sectional representation the outer line does not run parallel to the piston axis/cylinder wall, but instead it is arched outwards and is inclined. In a case, the person skilled in the art understands the term “pivot point” to mean the radially outermost point of the convexity/conicity (vertex) or also the maximum point of the bearing surface profile or also the reversal point of the bearing surface profile in the installed state of the piston ring. In the circumferential direction, a “pivot line” is created, as it were. According to one embodiment, a region surrounding the pivot point is not furnished with a protective layer. Consequently, a kind of band results in the circumferential direction on the piston ring bearing surface, to which no protective layer is applied, this band being located as it were in a region around the “pivot line”. On the other hand, the regions of the bearing surface, including the running edges, which are not located in this region around the pivot point, are furnished with a protective layer.

In this context, the thickness of the protective layer varies by a few μm, but 5 μm should not be exceeded, the thickness of the protective layer is preferably less than 2 μm, most preferable is a thickness of less than 1 μm.

According to one embodiment, a metal or a metal nitride is used as the material for the protective layer.

Various methods for applying such a protective layer are known to the person skilled in the art. According to one possible embodiment of the present invention, the protective layer is applied to the DLC layer in a physical vapour deposition (PVD) method.

It is also conceivable to apply an additional layer between the DLC layer and the protective layer.

According to a preferred embodiment, the protective layer is in the form of deposits in depressions in the surface of the functional coating. In this context, the term depressions in the surface is understood to mean depressions which exist due to the roughness of the surface. Thus, the protective layer then does not have the form of a closed surface, but is rather a series of microscopically small surface deposits spread over the entire surface.

The dimensions of the depressions and the deposits may be adjusted via the process for producing the functional coating. Here it has been found that for thinner functional coatings, i.e. in this case less than 10 μm, an area percentage of the surface deposits relative to the total surface area in the range from 10% to 30% is preferable, whereas with thicker functional coatings the area percentage should also be greater. More precisely, for layer thicknesses greater than 10 μm an area percentage from 20% to 40% of the total thickness is preferable. Thus, the area percentage of the surface deposits should also increase as the functional coating becomes thicker. The Rpk roughness value on the piston ring bearing surface is in the range from 0.03 μm to 0.1 μm; the Rk roughness value on the piston ring bearing surface is in the range from 0.15 μm to 0.3 μm.

According to the invention, a piston ring with a protective layer in the form of surface deposits in the functional coating is produced as described in the following section. First a diamond-like carbon (DlC) layer is applied to serve as a functional coating, that is to say a wear protection layer on a piston ring body, which is made for example from grey cast iron or a steel. A protective layer is further applied over this DLC layer, and in a subsequent step is removed again to such an extent that the additional layer, i.e. the protective layer only remains in depressions in the DLC layer. Thus, there are deposits present in in depressions on the surface of the DLC layer which are created due to the surface roughness of the DLC layer.

This additional layer in the form of preferably metal deposits causes a mixture of oil and carbon and also a metal a protective layer to develop between the cylinder wall and the piston ring surface. The friction coefficient is reduced by the further removal of the protective layer, so that the wear behaviour, particularly the running-in behaviour, is improved. In an engine trial lasting 100 hours, an improvement was observed in the running-in behaviour of a piston ring produced according to the invention, i.e. with the additional surface deposits in the wear protection layer. It particular, it was found that the coating wear is reduced by approximately 15% and liner wear at TDC is reduced by approximately 25%.

For such surface deposits in the DLC functional coating, the DLC layer must exhibit a certain roughness. According to one embodiment, this roughness is adjusted by roughing the piston ring body before the application of the functional coating, at least at the sites where a functional coating is to be applied. This roughness is then “transferred” to the surface of functional coating. According to a further embodiment, the DLC layer is applied by an electric arc process or a sputtering process (both are PVD processes) in order to create a certain basic roughness. Of course it is also conceivable to combine roughing the piston ring body with the application of the DLC layer with electric arc/sputtering processes. Before the protective layer is applied, the surface of the functional coating (DLC layer) preferably has a Rpk roughness value in the range from 0.15 μm to 0.5 μm, and a Rk roughness value Rk in the range from 0.3 μm to 0.7 μm.

The roughness values generally apply to the total axial height of the piston ring bearing surface, and if the bearing surface is processed subsequently the (metal) protective layer may be distributed on the bearing surface, i.e. above and below the ring lapping. These regions may be of different widths, from 0.05 mm to 4 mm depending on the axial height.

The material used for the protective layer is preferably a metal, a metal alloy or a metal nitride, particularly preferably chromium, aluminium, titanium nitride or vanadium nitride. The material of the protective layer is preferably applied up to a thickness in the range from 0.05 μm to 1 μm. More preferably, in the case of a DLC layer thickness greater than 20 μm an application thickness of the protective layer material is preferably between 0.2 μm and 0.4 μm. In the case of a DLC layer thickness less than 20 μm, an application thickness of the protective layer material is preferably between 0.05 μm and 0.4 μm, most preferably between 0.1 μm and 0.2 μm. A PVD process is used preferably to apply the protective layer.

After a layer of the protective layer material has been applied, it is partly removed again in a subsequent removal step by means of a suitable process. In this context, lapping and particularly cylindrical lapping processes preferred. The removal is continued until deposits of the protective layer material only remain in depressions due to the roughness of the surface of the DLC layer. In this way, surface deposits are formed on the DLC layer. The removal process is preferably continued until the area of the surface deposits as a percentage of the total surface area is in the range from 10% to 30% for thinner DLC layers, i.e. smaller than 10 μm. In the case of thicker DLC layers, i.e. greater than 10 μm, an area percentage in the range from 20% to 40% is preferred. In this context, the area percentage may be determined by means of raster electron microscope (REM) mapping process. Here, the term total surface area is understood to be the total area over which the method according to the invention is applied, including the removal process, i.e. the area percentage is percentage of the surface area from which the protective layer material is removed. It is also conceivable to apply the protective layer over only a part of the DLC layer, and/or only to remove the protective layer material from a partial area, whereas in other partial areas the applied protective layer remains in its full thickness. It is also possible to remove different thicknesses of the protective layer material at different partial areas, for example it would be conceivable to remove rather more of the material in the abutment area of the piston ring.

The application of the protective layer material over the functional coating and and the subsequent removal process have the effect of reducing the Rpk roughness value by about 20% and that of the Rk roughness value by about 30%. This change refers to the functional coating with surface deposits, i.e. after the removal step, compared to the functional coating without surface deposits, i.e. directly after the application of the DLC layer/functional coating. The roughness values are thus reduced significantly, which leads to an improvement in the wear behaviour.

1-19. (canceled)

20. A piston ring, comprising a piston ring body,
wherein a DLC layer is applied to the outer surface of the piston ring body, at least to a bearing surface of said outer surface, as a functional coating,
wherein a protective layer is applied over the functional coating at least on partial surfaces of the piston ring bearing surface,
wherein the protective layer consists of a material which is different from the material of the functional coating and has greater thermal resistance that the functional coating material,
wherein the protective layer is present in the form of surface deposits in recesses in the functional coating.

21. The piston ring according to claim 20, wherein the protective layer was applied in a PVD process.

22. The piston ring according to claim 20, wherein the thickness of the protective layer is less than 5 μm.

23. The piston ring according to claim 20, wherein the protective layer consists of a metal or a metal nitride.

24. The piston ring according to claim 20, wherein a protective layer is applied to the entire piston ring bearing surface.

25. The piston ring according to claim 20, wherein no protective layer is applied to a region of the piston ring bearing surface around a pivot point, and wherein a protective layer is applied to the rest of the piston ring bearing surface and the running edges outside of this pivot point region.

26. The piston ring according to claim 20, wherein the functional coating is formed as a DLC layer that is free from hydrogen and halogens.

27. The piston ring according to claim 20, wherein the surface deposits of the protective layer occupy an area percentage between 10% and 30% of the total surface area when the functional coating has a layer thickness of less than 10 μm and an area percentage between 20% and 40% of the total surface area when the functional coating has a layer thickness of more than 10 μm.

28. The piston ring according to claim 20, wherein the piston ring hearing surface has an Rpk roughness valve range from 0.03 μm to 0.1 μm and an Rk roughness value in the range from 0.15 μm to 0.3 μm.

29. A method for producing a coated piston ring, comprising
providing a piston ring body;
applying a DLC layer as a functional coating at least to a bearing surface of the piston ring body;
applying a protective layer over the functional coating;
partially removing the protective layer, so that only deposits are left in depressions in the surface of the functional coating.

30. The method according to claim 29, wherein those surfaces that are furnished with a functional coating are roughed before the functional coating is applied.

31. The method according to claim 29, wherein the functional coating is applied in an electric arc process for a sputtering process.

32. The method according to claim 29, wherein after its application the functional coating has a Rpk roughness value in the range from 0.15 μm to 0.5 μm, and a Rk roughness value in the range from 0.3 μm to 0.7 μm.

33. The method according to claim 29 wherein the protective layer is applied with a PVD process.

34. The method according to claim 29, wherein the material of the protective layer comprises a metal, a metal alloy or a metal nitride, preferably chromium, aluminium, titanium nitride or vanadium nitride.

35. The method according to claim 29, wherein the application thickness of the protective layer material is between 0.05 μm and 1 μm, preferably between 0.2 μm and 0.4 μm for a layer thickness of the functional coating greater than 20 μm, or preferably between 0.05 μm and 0.4 μm, more preferably between 0.1 μm and 0.2 μm for a layer thickness of the functional coating less than 20 μm.

36. The method according to claim 29, wherein the removal step comprises lapping, particularly cylindrical lapping.

37. The method according to claim 29, wherein the removal step is continues until the area percentage of the surface deposits is between 10% and 30% of the total surface area with a layer thickness of the functional coating less than 10 μm, and between 20% and 40% of the total surface area with a layer thickness of the functional coating greater than 10 μm.

38. The piston ring according to claim 20, wherein the thickness of the protective layer is less than 2 μm.

39. The piston ring according to claim 20, wherein the thickness of the protective layer is less than 1 μm.
